(19) United States
(12) Patent Application Publication
(10) Pub. No.: US 2012/0044965 A1
(43) Pub. Date: Feb. 23, 2012

(54) SEMICONDUCTOR LASER APPARATUS AND OPTICAL APPARATUS

(75) Inventors: Shinichiro Akiyoshi, Kurayoshi-shi (JP); Gen Shimizu, Tottori-shi (JP); Daiki Mihashi, Tottori-shi (JP)

(73) Assignees: SANYO Optec Design Co., Ltd., Bunkyo-ku (JP); Sanyo Electric Co., Ltd., Moriguchi-shi (JP)

(21) Appl. No.: 13/207,020

(22) Filed: Aug. 10, 2011

(30) Foreign Application Priority Data
Aug. 20, 2010 (JP) 2010-184617

(51) Int. Cl. H01S 5/40

(52) U.S. Cl. 372/50.12

(57) ABSTRACT

This semiconductor laser apparatus includes a base having a step portion, a first upper surface on a lower side of the step portion and a second upper surface on an upper side of the step portion, a first semiconductor laser device bonded onto the first upper surface, having a first light-emitting region on an upper side thereof, and a second semiconductor laser device bonded onto the second upper surface, having a second light-emitting region on a lower side thereof. The first light-emitting region is located above the second upper surface in a state where the base is horizontally arranged.

### CROSS-REFERENCE TO RELATED APPLICATION

The priority application number JP2010-184617, Semiconductor Laser Apparatus and Optical Apparatus, Aug. 20, 2010, Shinichiro Akiyoshi et al., upon which this patent application is based is hereby incorporated by reference.

### BACKGROUND OF THE INVENTION

1. Field of the Invention

The present invention relates to a semiconductor laser apparatus and an optical apparatus, and more particularly, it relates to a semiconductor laser apparatus and an optical apparatus each comprising a base including a first upper surface and a second upper surface having different heights from each other.

2. Description of the Background Art

A semiconductor laser apparatus (optical apparatus) mounted with a plurality of semiconductor laser devices on a base including a first upper surface and a second upper surface having different heights from each other is known in general, as disclosed in Japanese Patent Laying-Open No. 2000-222766, for example.

FIG. 7 in Japanese Patent Laying-Open No. 2000-222766 discloses a semiconductor laser apparatus (optical apparatus) comprising a submount (base) including a first upper surface and a second upper surface located above the first upper surface, a first semiconductor laser chip bonded onto the first upper surface, including a first light-emitting region located on a side (upper side) opposite to a side bonded to the first upper surface and a second semiconductor laser chip bonded onto the second upper surface, including a second light-emitting region located on a side (lower side) bonded to the second upper surface. In this optical apparatus, the first light-emitting region of the first semiconductor laser chip and the second light-emitting region of the second semiconductor laser chip are greatly separated from each other in a height direction in a state where the submount is horizontally arranged. In Japanese Patent Laying-Open No. 2000-222766, a beam emitted from the first light-emitting region of the first semiconductor laser chip and a beam emitted from the second light-emitting region of the second semiconductor laser chip are reflected by a wavelength selective film and a reflective device, whereby an optical axis of the laser beam from the first semiconductor laser chip and an optical axis of the laser beam from the second semiconductor laser chip are aligned on the same optical axis and the respective light-emitting regions of the laser chips are displaced on the optical axis.

In the optical apparatus disclosed in Japanese Patent Laying-Open No. 2000-222766, however, a height position of the first light-emitting region of the first semiconductor laser chip and a height position of the second light-emitting region of the second semiconductor laser chip are greatly separated from each other, and hence if this structure is applied to a structure in which the laser beam from the first semiconductor laser chip and the laser beam from the second semiconductor laser device are incident upon a lens without the wavelength selective film and the reflective device, for example, an application position (spot) of the laser beam from the first semiconductor laser chip and an application position of the laser beam from the second semiconductor laser chip are disadvantageously greatly deviated from each other in the height direction.

### SUMMARY OF THE INVENTION

A semiconductor laser apparatus according to a first aspect of the present invention comprises a base including a step portion, a first upper surface on a lower side of the step portion and a second upper surface on an upper side of the step portion, a first semiconductor laser device bonded onto the first upper surface, including a first light-emitting region on an upper side thereof, and a second semiconductor laser device bonded onto the second upper surface, including a second light-emitting region on a lower side thereof, wherein the first light-emitting region is located above the second upper surface in a state where the base is horizontally arranged.

An optical apparatus according to a second aspect of the present invention comprises a semiconductor laser apparatus including a base having a step portion, a first upper surface on a lower side of the step portion and a second upper surface on an upper side of the step portion, a first semiconductor laser device bonded onto the first upper surface, having a first light-emitting region on an upper side thereof and a second semiconductor laser device bonded onto the second upper surface, having a second light-emitting region on a lower side thereof, and an optical system controlling a laser beam emitted from the semiconductor laser apparatus, wherein the first light-emitting region is located above the second upper surface in a state where the base is horizontally arranged.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a top plan view of a two-wavelength semiconductor laser apparatus according to a first embodiment of the present invention;

FIG. 2 is a front elevational view of the two-wavelength semiconductor laser apparatus according to the first embodiment of the present invention, as viewed from a laser beam emitting direction;

FIGS. 3 to 5 are sectional views for illustrating a manufacturing process of the two-wavelength semiconductor laser apparatus according to the first embodiment of the present invention;

FIG. 6 is a front elevational view of a three-wavelength semiconductor laser apparatus according to a second embodiment of the present invention, as viewed from a laser beam emitting direction;

FIGS. 7 and 8 are sectional views for illustrating a manufacturing process of the three-wavelength semiconductor laser apparatus according to the second embodiment of the present invention;

FIG. 9 is a schematic diagram showing a structure of an optical pickup according to a third embodiment of the present invention; and

FIG. 10 is a front elevational view of a two-wavelength semiconductor laser apparatus according to a modification of the first embodiment of the present invention, as viewed from a laser beam emitting direction.

### DESCRIPTION OF THE PREFERRED EMBODIMENTS

Embodiments of the present invention are hereinafter described with reference to the drawings.

### First Embodiment

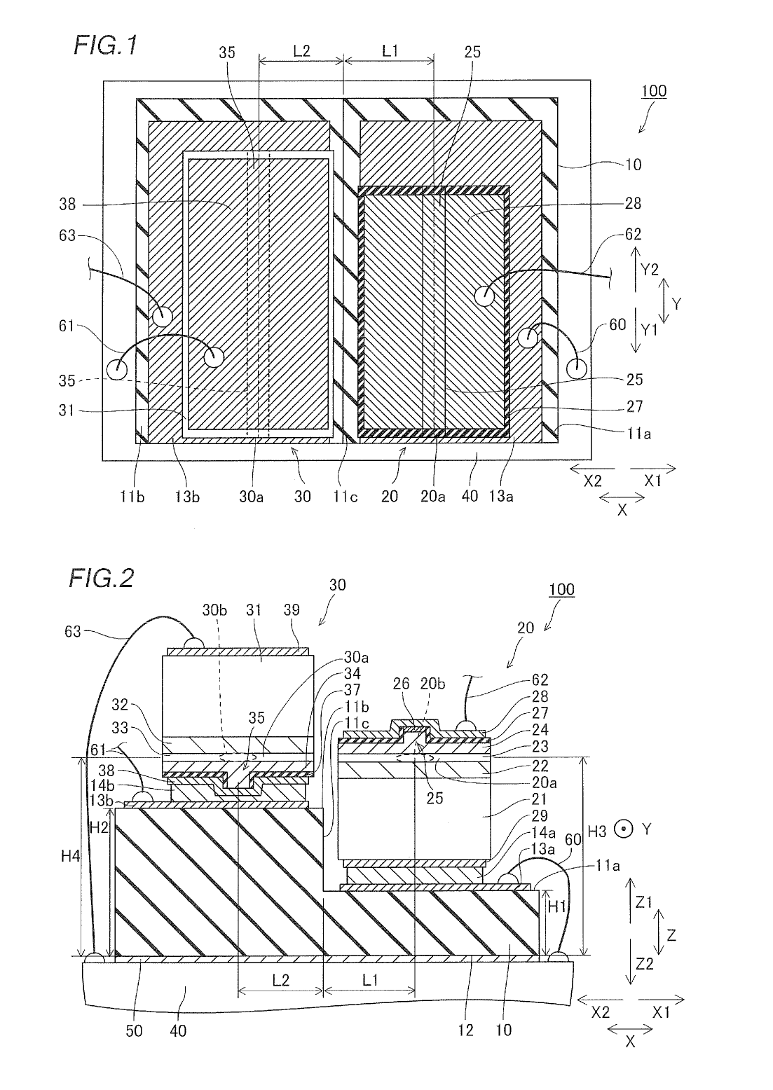

A structure of a two-wavelength semiconductor laser apparatus 100 according to a first embodiment of the present invention is now described with reference to FIGS. 1 and 2. The two-wavelength semiconductor laser apparatus 100 is an example of the “semiconductor laser apparatus” in the present invention.

The two-wavelength semiconductor laser apparatus 100 according to the first embodiment of the present invention comprises a heat radiation substrate 10 made of AlN having insulating properties, a blue-violet semiconductor laser device 20 having a lasing wavelength of about 405 nm and a red semiconductor laser device 30 having a lasing wavelength of about 650 nm both bonded to the heat radiation substrate 10, and a base portion 40 supporting the heat radiation substrate 10 from below (from a Z2 side), as shown in FIGS. 1 and 2. The base portion 40 is formed to horizontally arrange the heat radiation substrate 10 through a bonding layer 50 (see FIG. 2). The base portion 40 is connected to a cathode terminal (not shown). The heat radiation substrate 10 is an example of the “base” in the present invention. The blue-violet semiconductor laser device 20 is an example of the “first semiconductor laser device” in the present invention, and the red semiconductor laser device 30 is an example of the “second semiconductor laser device” in the present invention.

The heat radiation substrate 10 includes a step portion 11c and upper surfaces 11a and 11b formed at heights different from each other (in a direction Z) through the step portion 11c. Specifically, the upper surface 11a is located on a lower side (Z2 side) of the step portion 11c and formed at a height H1 upward from (on a Z1 side of) a lower surface 12 of the heat radiation substrate 10. The upper surface 11b is located on an upper side (Z1 side) of the step portion 11c and formed at a height H2 upward from the lower surface 12 of the heat radiation substrate 10. The height H2 is larger than the height H1. The blue-violet semiconductor laser device 20 and the red semiconductor laser device 30 are bonded onto the upper surfaces 11a and 11b, respectively. The upper surfaces 11a and 11b and the lower surface 12 of the heat radiation substrate 10 are formed to be flat. The upper surfaces 11a and 11b are examples of the “first upper surface” and the “second upper surface” in the present invention, respectively.

As shown in FIG. 1, the upper surface 11a of the heat radiation substrate 10 is located on one side (X1 side) in a direction (direction X) orthogonal to a direction Y, which is emitting directions of laser beams from the blue-violet semiconductor laser device 20 and the red semiconductor laser device 30 described later, and the upper surface 11b of the heat radiation substrate 10 is located on the other side (X2 side).

The step portion 11c is formed to extend along the emitting direction (direction Y) of the laser beam from the blue-violet semiconductor laser device 20 and the emitting direction (direction Y) of the laser beam from the red semiconductor laser device 30. The step portion 11c is formed to extend from one end of the heat radiation substrate 10 on a Y1 side to the other end thereof on a Y2 side. The step portion 11c is formed to extend vertically upward (in a direction Z1) from the upper surface 11a on the lower side and reach the upper surface 11b on the upper side, as shown in FIG. 2. In other words, a height of the step portion 11c in a vertical direction is a difference between the heights of the upper surfaces 11a and 11b (H2−H1).

Electrodes 13a and 13b are formed on the upper surfaces 11a and 11b of the heat radiation substrate 10, respectively. The blue-violet semiconductor laser device 20 is bonded to the electrode 13a through a solder layer 14a, and the red semiconductor laser device 30 is bonded to the electrode 13b through a solder layer 14b. The electrodes 13a and 13b are separated from each other in the direction X (device width direction) and the direction Z (height direction) by the step portion 11c. The electrodes 13a and 13b are examples of the “first electrode” and the “second electrode” in the present invention, respectively.

The blue-violet semiconductor laser device 20 is made of a nitride-based semiconductor. Specifically, in the blue-violet semiconductor laser device 20, an n-type cladding layer 22 made of n-type AlGaN is formed on an upper surface of an n-type GaN substrate 21, as shown in FIG. 2. An active layer 23 having a multiple quantum well (MQW) structure in which quantum well layers (not shown) made of InGaN and barrier layers (not shown) made of GaN are alternately stacked is formed on an upper surface of the n-type cladding layer 22. Luminous characteristics of the active layer 23 made of a nitride-based semiconductor are easily deteriorated due to accumulation of thermal stress if heat of about 300° C. is applied in bonding the blue-violet semiconductor laser device 20 onto the upper surface 11a of the heat radiation substrate 10. A p-type cladding layer 24 made of p-type AlGaN is formed on an upper surface of the active layer 23. A material constituting the n-type cladding layer 22, the active layer 23 and the p-type cladding layer 24 is an example of the “nitride-based semiconductor” in the present invention.

As shown in FIG. 1, a ridge portion (projecting portion) 25 extending along the direction Y is formed on the p-type cladding layer 24 in a substantially central portion of the blue-violet semiconductor laser device 20 in the direction X. The laser beam is emitted from a light-emitting surface 20a, which is a surface of the blue-violet semiconductor laser device 20 on one end (on a Y1 side) in the emitting direction (direction Y). At this time, the laser beam is emitted from a position of the active layer 23 corresponding to the ridge portion 25 on the light-emitting surface 20a, as shown in FIG. 2. In other words, a light-emitting region 20b (region surrounded by a broken line) of the blue-violet semiconductor laser device 20 is located in a position corresponding to the ridge portion 25 formed in the substantially central portion of the blue-violet semiconductor laser device 20 in the direction X at a height of the active layer 23. The light-emitting region 20b is an example of the “first light-emitting region” in the present invention. The ridge portion 25 is an example of the “first ridge portion” in the present invention.

A p-side ohmic electrode 26 in which a Pt layer, a Pd layer and a Pt layer are stacked successively from a side closer to the p-type cladding layer 24 is formed in an upper portion of the ridge portion 25 of the p-type cladding layer 24. A current blocking layer 27 made of SiO₂ is formed on an upper surface of the p-type cladding layer 24 other than the ridge portion 25, both side surfaces of the ridge portion 25 and both side surfaces of the p-side ohmic electrode 26. A p-side pad electrode 28 made of Au or the like is formed on upper surfaces of the p-side ohmic electrode 26 and the current blocking layer 27. An n-side electrode 29 in which an Al layer, a Pd layer and an Au layer are stacked successively from a side closer to the n-type GaN substrate 21 is formed on a substantially entire region of a lower surface of the n-type GaN substrate 21. This n-side electrode 29 is electrically connected to the electrode 13a and the base portion 40 through the solder layer 14a. An upper surface (on a Z1 side) of the p-side pad electrode 28 in the blue-violet semiconductor laser device 20 is an example of the “first surface” in the present invention.

The n-side electrode 29 formed on the lower surface of the n-type GaN substrate 21 and the upper surface 11a of the heat radiation substrate 10 are bonded onto each other, whereby the blue-violet semiconductor laser device 20 is bonded onto the upper surface 11a such that the active layer 23 and the ridge portion 25 are located above (on a Z1 side of) the n-type GaN substrate 21. In other words, the blue-violet semiconductor laser device 20 is bonded onto the upper surface 11a in a junction-up system, so that the light-emitting region 20b is located on a side (upper side (Z1 side)) opposite to a side bonded to the upper surface 11a. A lower surface of the n-side electrode 29 bonded onto the upper surface 11a is an example of the “second surface” in the present invention.

According to the first embodiment, a height H3 from the lower surface 12 of the heat radiation substrate 10 to the active layer 23 in the vertical direction (direction Z) is larger than the height H2 from the lower surface 12 of the heat radiation substrate 10 to the upper surface 11b in the vertical direction (H3>H2). Thus, the active layer 23 is located above (on a Z1 side of) the upper surface 11b on the upper side of the step portion 11c, whereby the light-emitting region 20b of the blue-violet semiconductor laser device 20 is located above the upper surface 11b on the upper side of the step portion 11c.

The red semiconductor laser device 30 is made of a GaInP-based semiconductor and is a semiconductor laser device where a larger amount of heat is generated than in the blue-violet semiconductor laser device 20. Specifically, in the red semiconductor laser device 30, an n-type cladding layer 32 made of AlGaInP is formed on a lower surface of an n-type GaAs substrate 31, as shown in FIG. 2. An active layer 33 having an MQW structure in which quantum well layers (not shown) made of GaInP and barrier layers (not shown) made of AlGaInP are alternately stacked is formed on a lower surface of the n-type cladding layer 32. Luminous characteristics of the active layer 33 made of a GaInP-based semiconductor are hardly deteriorated because thermal stress is hardly accumulated as compared with the active layer 23 of the blue-violet semiconductor laser device 20, even if heat of about 300° C. is applied in bonding the red semiconductor laser device 30 onto the upper surface 11b of the heat radiation substrate 10. A p-type cladding layer 34 made of AlGaInP is formed on a lower surface of the active layer 33. A material constituting the n-type cladding layer 32, the active layer 33 and the p-type cladding layer 34 is an example of the “GaInP-based semiconductor” in the present invention. As shown in FIG. 1, a ridge portion (projecting portion) 35 extending along the direction Y is formed on the p-type cladding layer 34 in a substantially central portion of the red semiconductor laser device 30 in the direction X. The laser beam is emitted from a light-emitting surface 30a, which is a surface of the red semiconductor laser device 30 on one end (on the Y1 side) in the emitting direction (direction Y). At this time, the laser beam is emitted from a position of the active layer 33 corresponding to the ridge portion 35 on the light-emitting surface 30a, as shown in FIG. 2. In other words, a light-emitting region 30b (region surrounded by a broken line) of the red semiconductor laser device 30 is located in a position corresponding to the ridge portion 35 formed in the substantially central portion of the red semiconductor laser device 30 in the direction X at a height of the active layer 33. The light-emitting region 30b is an example of the “second light-emitting region” in the present invention. The ridge portion 35 is an example of the “second ridge portion” in the present invention.

A current blocking layer 37 made of SiO₂ is formed on a lower surface of the p-type cladding layer 34 other than the ridge portion 35 and both side surfaces of the ridge portion 35. A p-side electrode 38 made of Au or the like is formed on lower surfaces of the ridge portion 35 and the current blocking layer 37. This p-side electrode 38 is connected to the electrode 13b and a lead terminal (on an anode side) (not shown) through the solder layer 14b. An n-side electrode 39 in which an AuGe layer, an Ni layer and an Au layer are stacked successively from a side closer to the n-type GaAs substrate 31 is formed on a substantially entire region of an upper surface of the n-type GaAs substrate 31. An upper surface (on a Z1 side) of the n-side electrode 39 in the red semiconductor laser device 30 is an example of the “fourth surface” in the present invention.

The p-side electrode 38 formed below (on a Z2 side of) the n-type GaAs substrate 31 and the upper surface 11b of the heat radiation substrate 10 are bonded onto each other, whereby the red semiconductor laser device 30 is bonded onto the upper surface 11b such that the active layer 33 and the ridge portion 35 are located below (on the Z2 side of) the n-type GaAs substrate 31. In other words, the red semiconductor laser device 30 is bonded onto the upper surface 11b in a junction-down system, so that the light-emitting region 30b is located on a side (lower side (Z2 side)) bonded to the upper surface 11b. A lower surface of the p-side electrode 38 bonded onto the upper surface 11b is an example of the “third surface” in the present invention.

According to the first embodiment, a height H4 from the lower surface 12 of the heat radiation substrate 10 to the active layer 33 of the red semiconductor laser device 30 in the vertical direction (direction Z) is substantially equal to the height H3 from the lower surface 12 of the heat radiation substrate 10 to the active layer 23 of the blue-violet semiconductor laser device 20 in the vertical direction. Thus, the light-emitting region 20b of the blue-violet semiconductor laser device 20 and the light-emitting region 30b of the red semiconductor laser device 30 are located at the heights substantially equal to each other and arranged such that height positions of at least portions thereof overlap each other. In this state, the light-emitting region 20b and the light-emitting region 30b are arranged along the emitting directions (direction Y) of the laser beams at the heights equal to each other or close to each other. The height (H2−H1) of the step portion 11c in the vertical direction is adjusted such that the light-emitting region 20b of the blue-violet semiconductor laser device 20 and the light-emitting region 30b of the red semiconductor laser device 30 are located at the heights substantially equal to each other.

According to the first embodiment, a distance L1 from the step portion 11c to the ridge portion 25 (light-emitting region 20b) of the blue-violet semiconductor laser device 20 in a horizontal direction (direction X) is substantially constant along the emitting direction (direction Y) of the laser beam, as shown in FIGS. 1 and 2. Similarly, a distance L2 from the step portion 11c to the ridge portion 35 (light-emitting region 30b) of the red semiconductor laser device 30 in the horizontal direction (direction X) is substantially constant along the emitting direction (direction Y) of the laser beam. In other words, the step portion 11c is formed such that the horizontal distance from the step portion 11c to each of the ridge portions (waveguides) of the laser devices is substantially constant along an extensional direction of a cavity. FIG. 1 shows that the distances L1 and L2 are from the step portion 11c to respective centerlines (dashed lines) of the ridge portions of the semiconductor laser devices.

The electrode 13a formed on the heat radiation substrate 10 and the base portion 40 are electrically connected with each other through a wire 60. The electrode 13b formed on the heat radiation substrate 10 and the lead terminal (on the anode side) (not shown) are electrically connected with each other through a wire 61. The p-side pad electrode 28 of the blue-violet semiconductor laser device 20 and a lead terminal (on the anode side) (not shown) are electrically connected with each other through a wire 62. The n-side electrode 39 of the red semiconductor laser device 30 and the base portion 40 are electrically connected with each other through a wire 63. The wires 60 and 61 are examples of the “bonding wire” in the present invention.

A manufacturing process of the two-wavelength semiconductor laser apparatus 100 according to the first embodiment is now described with reference to FIGS. 2 to 5.

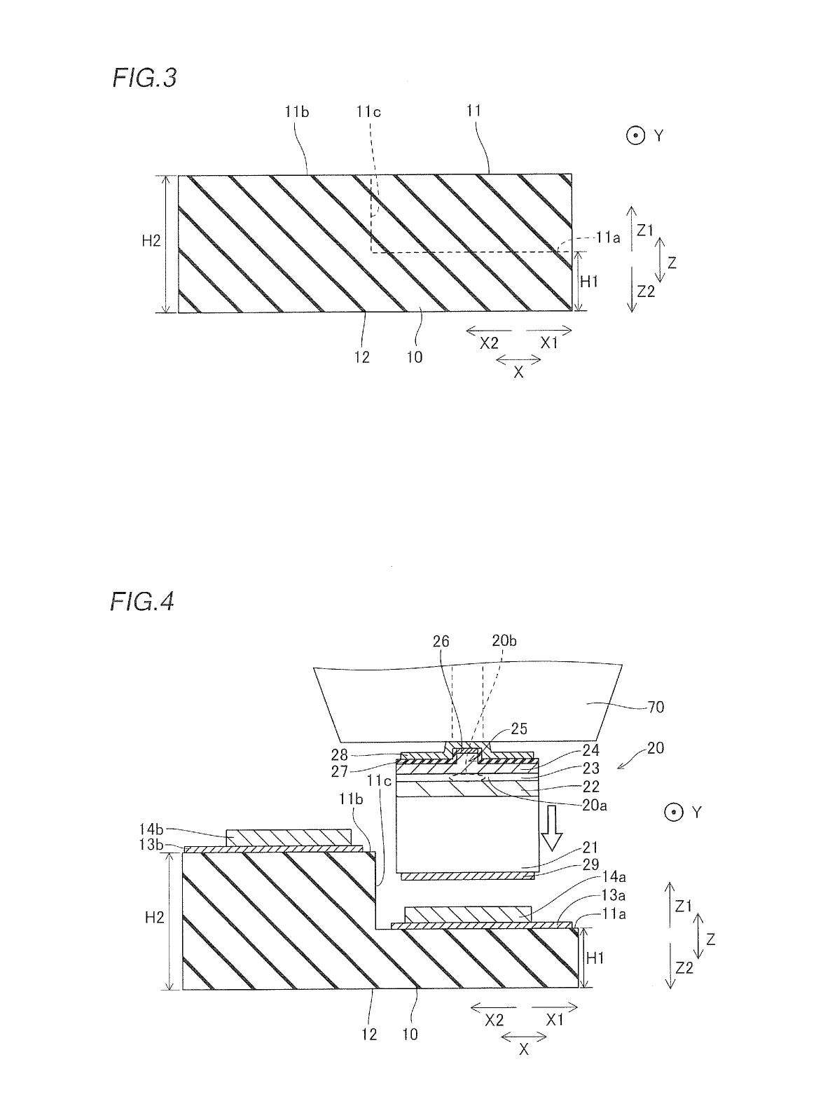

As shown in FIG. 3, a prescribed region of an upper surface 11 of a plate-like heat radiation substrate 10 on the X1 side is first etched by a prescribed depth (H2−H1) in the vertical direction (direction Z), thereby forming the heat radiation substrate 10 having the upper surfaces 11a and 11b and the step portion 11c. At this time, the height (H2−H1) (the quantity of etching) of the step portion 11c in the vertical direction is adjusted such that the light-emitting region 20b of the blue-violet semiconductor laser device 20 and the light-emitting region 30b of the red semiconductor laser device 30 are located at the heights substantially equal to each other when the blue-violet semiconductor laser device 20 and the red semiconductor laser device 30 are bonded onto the upper surfaces 11a and 11b of the heat radiation substrate 10 in a later process.

Then, the electrodes 13a and 13b are formed on the upper surfaces 11a and 11b of the heat radiation substrate 10, respectively, as shown in FIG. 4. Thereafter, the solder layers 14a and 14b are formed on the electrodes 13a and 13b, respectively.

The blue-violet semiconductor laser device 20 and the red semiconductor laser device 30 are formed through prescribed manufacturing processes. The p-side pad electrode 28 of the blue-violet semiconductor laser device 20 is grasped from above (from a Z1 side) with a collet 70 such that the n-side electrode 29 of the blue-violet semiconductor laser device 20 and the solder layer 14a are opposed to each other. Then, the n-side electrode 29 of the blue-violet semiconductor laser device 20 and the electrode 13a are bonded to each other through the solder layer 14a melted by applying heat of about 300° C. At this time, the blue-violet semiconductor laser device 20 is bonded onto the upper surface 11a (electrode 13a) of the heat radiation substrate 10 in a junction-up system, so that the light-emitting region 20b is located on the side (upper side (Z1 side)) opposite to the side bonded to the upper surface 11a. The blue-violet semiconductor laser device 20 is bonded onto the upper surface 11a such that the height from the lower surface 12 of the heat radiation substrate 10 to the active layer 23 of the blue-violet semiconductor laser device 20 in the vertical direction (direction Z) is H3 (see FIG. 5).

Thereafter, the n-side electrode 39 of the red semiconductor laser device 30 is grasped from above (from the Z1 side) with the collet 70 such that the p-side electrode 38 of the red semiconductor laser device 30 and the solder layer 14b are opposed to each other, as shown in FIG. 5. Then, the p-side electrode 38 of the red semiconductor laser device 30 and the electrode 13b are bonded to each other through the solder layer 14b melted by applying heat of about 300° C. At this time, the red semiconductor laser device 30 is bonded onto the upper surface 11b (electrode 13b) of the heat radiation substrate 10 such that the height from the lower surface 12 of the heat radiation substrate 10 to the active layer 33 of the red semiconductor laser device 30 in the vertical direction (direction Z) is H4 (see FIG. 2). Thus, the light-emitting region 20b of the blue-violet semiconductor laser device 20 and the light-emitting region 30b of the red semiconductor laser device 30 are located at the heights substantially equal to each other and arranged such that the height positions of at least the portions thereof overlap each other. The red semiconductor laser device 30 is bonded onto the upper surface 11b of the heat radiation substrate 10 in a junction-down system, so that the light-emitting region 30b is located on the side (lower side (Z2 side)) bonded to the upper surface 11b.

Thereafter, the heat radiation substrate 10 is bonded to the base portion 40 through the bonding layer 50, as shown in FIG. 2. At this time, the upper surfaces 11a and 11b and the lower surface 12 of the heat radiation substrate 10 are horizontally arranged. Then, the electrode 13a and the base portion 40 are connected with each other through the wire 60. The electrode 13b and the lead terminal (on the anode side) (not shown) are connected with each other through the wire 61. The p-side pad electrode 28 and the lead terminal (on the anode side) (not shown) are connected with each other through the wire 62. The n-side electrode 39 and the base portion 40 are connected with each other through the wire 63. Thus, the two-wavelength semiconductor laser apparatus 100 is formed.

According to the first embodiment, as hereinabove described, the light-emitting region 20b on an upper side (Z1 side) of the blue-violet semiconductor laser device 20 bonded onto the upper surface 11a on the lower side of the step portion 11c is located above (on the Z1 side of) the upper surface 11b on the upper side of the step portion 11c, onto which the red semiconductor laser device 30 is bonded, in a state where the heat radiation substrate 10 is horizontally arranged, whereby the light-emitting region 20b located on the upper side of the blue-violet semiconductor laser device 20 can be rendered closer to the light-emitting region 30b located on a lower side (Z2 side) of the red semiconductor laser device 30 bonded onto the upper surface 11b. Thus, the height (H3) of the light-emitting region 20b in the blue-violet semiconductor laser device 20 and the height (H4) of the light-emitting region 30b in the red semiconductor laser device 30 can be rendered close to each other in the structure having the blue-violet semiconductor laser device 20 and the red semiconductor laser device 30 mounted on the same heat radiation substrate 10.

According to the first embodiment, the height (H4) from the lower surface 12 of the heat radiation substrate 10 to the active layer 33 of the red semiconductor laser device 30 in the vertical direction (direction Z) is rendered substantially equal to the height (H3) from the lower surface 12 of the heat radiation substrate 10 to the active layer 23 of the blue-violet semiconductor laser device 20 in the vertical direction, whereby the light-emitting region 20b of the blue-violet semiconductor laser device 20 and the light-emitting region 30b of the red semiconductor laser device 30 are located at the heights substantially equal to each other and arranged such that the height positions of at least the portions thereof overlap each other. Thus, the height (H3) of the light-emitting region 20b and the height (H4) of the light-emitting region 30b can be reliably rendered close to each other.

According to the first embodiment, the light-emitting regions 20b and 30b extend along the emitting directions of the laser beams from the blue-violet semiconductor laser device 20 and the red semiconductor laser device 30.

The light-emitting regions 20b and 30b are arranged along the emitting directions (direction Y) of the laser beams at the heights equal to each other or close to each other. Thus, an optical axis of the laser beam in the blue-violet semiconductor laser device 20 and an optical axis of the laser beam in the red semiconductor laser device 30 can be aligned in the substantially same direction (direction Y).

According to the first embodiment, the height (H2−H1) of the step portion 11c in the vertical direction is adjusted such that the light-emitting region 20b of the blue-violet semiconductor laser device 20 and the light-emitting region 30b of the red semiconductor laser device 30 are located at the heights substantially equal to each other, whereby the heights of the light-emitting regions 20b and 30b can be adjusted by simply adjusting the height of the step portion 11c of the heat radiation substrate 10. Thus, the semiconductor laser apparatus 100 can be easily manufactured employing the versatile blue-violet semiconductor laser device 20 and the versatile red semiconductor laser device 30 both formed through the normal manufacturing processes.

According to the first embodiment, the lower surface of the n-side electrode 29 of the blue-violet semiconductor laser device 20 is bonded onto the upper surface 11a through the solder layer 14a. Thus, the blue-violet semiconductor laser device 20 is bonded to the heat radiation substrate 10 in a junction-up system, and hence the light-emitting region 20b of the blue-violet semiconductor laser device 20 can be easily arranged above the upper surface 11b of the heat radiation substrate 10.

According to the first embodiment, the lower surface of the p-side electrode 38 of the red semiconductor laser device 30 is bonded onto the upper surface 11b through the solder layer 14b. Thus, the red semiconductor laser device 30 is bonded to the heat radiation substrate 10 in a junction-down system, and hence the light-emitting region 30b of the red semiconductor laser device 30 can be easily rendered close to the light-emitting region 20b of the blue-violet semiconductor laser device 20 located above the upper surface 11b of the heat radiation substrate 10.

According to the first embodiment, the amount of heat generation in the red semiconductor laser device 30 is larger than the amount of heat generation in the blue-violet semiconductor laser device 20. Thus, the red semiconductor laser device 30 where a larger amount of heat is generated is bonded to the heat radiation substrate 10 in a junction-down system, and hence heat generated in the red semiconductor laser device 30 can be easily radiated to the heat radiation substrate 10.

According to the first embodiment, the upper surface (on the Z1 side) of the n-side electrode 39 of the red semiconductor laser device 30 is located above the upper surface (on the Z1 side) of the p-side pad electrode 28 of the blue-violet semiconductor laser device 20. Thus, the red semiconductor laser device 30 can be easily bonded onto the upper surface 11b of the heat radiation substrate 10 to which the blue-violet semiconductor laser device 20 is previously bonded without influence of a height of the blue-violet semiconductor laser device 20 in the manufacturing process.

According to the first embodiment, the step portion 11c is formed to extend in the direction Y along the emitting directions of the laser beams from the blue-violet semiconductor laser device 20 and the red semiconductor laser device 30, whereby the laser beam from the red semiconductor laser device 30 bonded onto the upper surface 11b is not blocked by the upper surface 11a or the blue-violet semiconductor laser device 20 bonded onto the upper surface 11a, dissimilarly to a case where the step portion 11c extends in a direction intersecting with the emitting directions (direction Y). Thus, a range to which the red semiconductor laser device 30 can emit the laser beam can be inhibited from decrease.

According to the first embodiment, the distance L1 from the step portion 11c to the ridge portion 25 of the blue-violet semiconductor laser device 20 in the horizontal direction is substantially constant along the emitting direction (direction Y) of the laser beam. The distance L2 from the step portion 11c to the ridge portion 35 of the red semiconductor laser device 30 in the horizontal direction is substantially constant along the emitting direction (direction Y) of the laser beam. Thus, the optical axis of the laser beam emitted from the blue-violet semiconductor laser device 20 and the optical axis of the laser beam emitted from the red semiconductor laser device 30 can be aligned as much as possible with reference to the step portion 11c.

According to the first embodiment, the blue-violet semiconductor laser device 20 made of a nitride-based semiconductor is employed as the first semiconductor laser device, and the red semiconductor laser device 30 made of a GaInP-based semiconductor is employed as the second semiconductor laser device. According to the first embodiment, the light-emitting region 20b of the blue-violet semiconductor laser device 20 is located on the upper side (the side opposite to the side bonded to the upper surface 11a), and hence even the blue-violet semiconductor laser device 20 made of a nitride-based semiconductor easily influenced by heat in bonding can be inhibited from being influenced by the heat in bonding when the blue-violet semiconductor laser device 20 is bonded onto the upper surface 11a of the heat radiation substrate 10. Thus, deterioration of luminous characteristics due to the heat in bonding can be inhibited. Further, the light-emitting region 30b of the red semiconductor laser device 30 is located on the side bonded to the upper surface 11b (a side closer to the heat radiation substrate 10 (lower side)), and hence heat generated in the light-emitting region 30b when the laser beam is emitted from the red semiconductor laser device 30 can be easily radiated to the heat radiation substrate 10.

According to the first embodiment, the heat radiation substrate 10 made of AlN having insulating properties is employed. The heat radiation substrate 10 comprises the electrode 13a formed on the upper surface 11a of the step portion 11c and the electrode 13b formed on the upper surface 11b of the step portion 11c. Thus, power can be easily supplied to the blue-violet semiconductor laser device 20 and the red semiconductor laser device 30 employing the electrode 13a formed on the upper surface 11a and the electrode 13b formed on the upper surface 11b even on the heat radiation substrate 10 including the step portion 11c. Further, deviation in the height direction between an application position of the laser beam from the blue-violet semiconductor laser device 20 and an application position of the laser beam from the red semiconductor laser device 30 can be easily inhibited from increase by effectively employing the heat radiation substrate 10 constituting the two-wavelength semiconductor laser apparatus 100.

According to the first embodiment, the electrodes 13a and 13b are separated from each other by the step portion 11c and connected with the wires 60 and 61, respectively. Thus, the electrodes 13a and 13b can be easily isolated from each other by effectively employing the step portion 11c. Further, the wires 60 and 61 are bonded at heights different from each other, and hence contact between the wires 60 and 61 can be easily inhibited.

### Second Embodiment

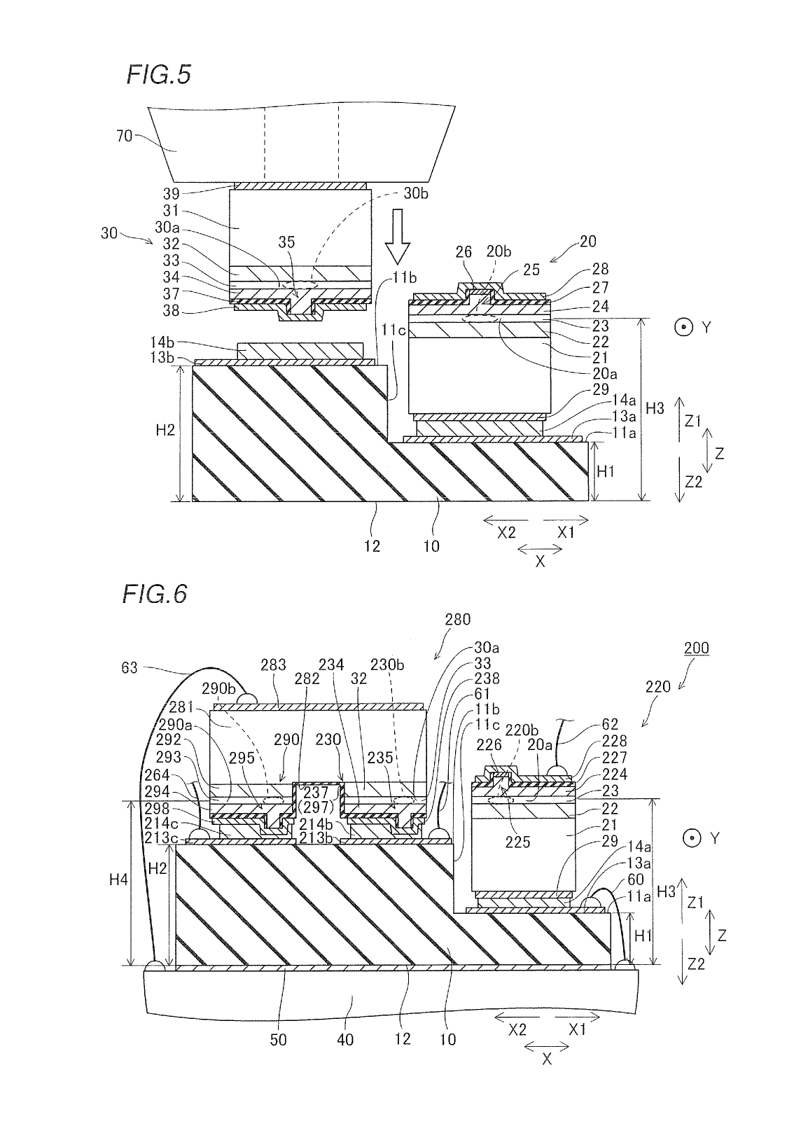

A second embodiment is described with reference to FIGS. 6 to 8. In a three-wavelength semiconductor laser apparatus 200 according to this second embodiment, a two-wavelength semiconductor laser device 280 having a red semiconductor laser device 230 and an infrared semiconductor laser device 290 monolithically formed on the same GaAs substrate 281 is employed in place of the red semiconductor laser device 30 of the first embodiment. In the figures, a structure similar to that of the two-wavelength semiconductor laser apparatus 100 according to the first embodiment is denoted by the same reference numerals. The three-wavelength semiconductor laser apparatus 200 is an example of the “semiconductor laser apparatus” in the present invention.

A structure of the three-wavelength semiconductor laser apparatus 200 according to the second embodiment of the present invention is now described with reference to FIG. 6.

The three-wavelength semiconductor laser apparatus 200 according to the second embodiment comprises a heat radiation substrate 10, a blue-violet semiconductor laser device 220 having a lasing wavelength of about 405 nm, the two-wavelength semiconductor laser device 280 having the red semiconductor laser device 230 with a lasing wavelength of about 650 nm and the infrared semiconductor laser device 290 with a lasing wavelength of about 780 nm monolithically formed and a base portion 40, as shown in FIG. 6. The blue-violet semiconductor laser device 220 is bonded onto an upper surface 11a of the heat radiation substrate 10 on an X1 side, and the two-wavelength semiconductor laser device 280 is bonded onto an upper surface 11b of the heat radiation substrate 10 on an X2 side. The blue-violet semiconductor laser device 220 is an example of the “first semiconductor laser device” in the present invention, and the red semiconductor laser device 230 and the infrared semiconductor laser device 290 are an example of the “second semiconductor laser device” in the present invention.

A ridge portion 225 formed on a p-type cladding layer 224 of the blue-violet semiconductor laser device 220 deviates to a step portion 11c (X2 side) from a center of the blue-violet semiconductor laser device 220 in a direction X (horizontal direction). In other words, a light-emitting region 220b of the blue-violet semiconductor laser device 220 deviates to the step portion 11c (X2 side) from the center of the blue-violet semiconductor laser device 220 in the direction X (horizontal direction). A p-side ohmic electrode 226, a current blocking layer 227 and a p-side pad electrode 228 are formed to correspond to the ridge portion 225. The ridge portion 225 is an example of the “first ridge portion” in the present invention.

Electrodes 213b and 213c are formed on the upper surface 11b of the heat radiation substrate 10. The electrode 213b is formed on a side (X1 side) closer to the step portion 11c, and the electrode 213c is formed on a side (X2 side) farther from the step portion 11c. The red semiconductor laser device 230 of the two-wavelength semiconductor laser device 280 is bonded onto the electrode 213b through a solder layer 214b, and the infrared semiconductor laser device 290 of the two-wavelength semiconductor laser device 280 is bonded onto the electrode 213c through a solder layer 214c. The electrodes 213b and 213c are examples of the “second electrode” in the present invention.

In the two-wavelength semiconductor laser device 280, the red semiconductor laser device 230 and the infrared semiconductor laser device 290 are monolithically formed on the common (same) n-type GaAs substrate 281. The red semiconductor laser device 230 is formed on the X1 side on a lower surface of the n-type GaAs substrate 281, and the infrared semiconductor laser device 290 is formed on the X2 side on the lower surface of the n-type GaAs substrate 281. The red semiconductor laser device 230 and the infrared semiconductor laser device 290 are separated from each other through a groove portion 282 formed in a substantially central portion of the lower surface of the n-type GaAs substrate 281 in the direction X. The n-type GaAs substrate 281 is an example of the “substrate” in the present invention.

The red semiconductor laser device 230 is formed with an n-type cladding layer 32, an active layer 33, a p-type cladding layer 234, a current blocking layer 237 and a p-side electrode 238 on the X1 side on the lower surface of the n-type GaAs substrate 281. The current blocking layer 237 is formed integrally with a current blocking layer 297 of the infrared semiconductor laser device 290 described later.

A ridge portion 235 formed on the p-type cladding layer 234 of the red semiconductor laser device 230 deviates to the step portion 11c (X1 side) from a center of the red semiconductor laser device 230 in the direction X (horizontal direction). In other words, a light-emitting region 230b of the red semiconductor laser device 230 deviates to the step portion 11c (X1 side) from the center of the red semiconductor laser device 230 in the direction X (horizontal direction). The current blocking layer 237 and the p-side electrode 238 are formed to correspond to the ridge portion 235. The ridge portion 235 is an example of the “second ridge portion” in the present invention. The infrared semiconductor laser device 290 is made of a GaAs-based semiconductor. Specifically, the infrared semiconductor laser device 290 is formed with an n-type cladding layer 292 made of AlGaAs on the X2 side on the lower surface of the n-type GaAs substrate 281. An active layer 293 having an MQW structure in which quantum well layers made of AlGaAs having a lower Al composition and barrier layers made of AlGaAs having a higher Al composition are alternately stacked is formed on a lower surface of the n-type cladding layer 292. Luminous characteristics of the active layer 293 made of a GaAs-based semiconductor are hardly deteriorated because thermal stress is hardly accumulated as compared with an active layer 23 of the blue-violet semiconductor laser device 220, even if heat of about 300° C. is applied in bonding the infrared semiconductor laser device 290 (two-wavelength semiconductor laser device 280) onto the upper surface 11b of the heat radiation substrate 10. A p-type cladding layer 294 made of AlGaAs is formed on a lower surface of the active layer 293. A material constituting the n-type cladding layer 292, the active layer 293 and the p-type cladding layer 294 is an example of the “GaAs-based semiconductor” in the present invention.

A ridge portion (projecting portion) 295 extending along a direction Y is formed on a portion of the p-type cladding layer 294 deviating to the step portion 11c (X1 side) from a center of the infrared semiconductor laser device 290 in the direction X (horizontal direction). A laser beam is emitted from a light-emitting surface 290a, which is a surface of the infrared semiconductor laser device 290 on one end (on a Y1 side) in an emitting direction (direction Y). At this time, the laser beam is emitted from a position of the active layer 293 corresponding to the ridge portion 295 on the light-emitting surface 290a, as shown in FIG. 2. In other words, a light-emitting region 290b (region surrounded by a broken line) of the infrared semiconductor laser device 290 is located in a position corresponding to the ridge portion 295 deviating to the step portion 11c (X1 side) from the center of the infrared semiconductor laser device 290 in the direction X (horizontal direction) at a height of the active layer 293. The light-emitting region 290b is an example of the “second light-emitting region” in the present invention. The ridge portion 295 is an example of the “second ridge portion” in the present invention.

The current blocking layer 297 formed integrally with the current blocking layer 237 of the red semiconductor laser device 230 is formed on a lower surface of the p-type cladding layer 294 other than the ridge portion 295 and both side surfaces of the ridge portion 295. A p-side electrode 298 made of Au or the like is formed on lower surfaces of the ridge portion 295 and the current blocking layer 297. This p-side electrode 298 is connected to the electrode 213c and a lead terminal (on an anode side) (not shown) through the solder layer 214c.

An n-side electrode 283 in which an AuGe layer, an Ni layer and an Au layer are stacked successively from a side closer to the n-type GaAs substrate 281 is formed on a substantially entire region of an upper surface of the n-type GaAs substrate 281.

The infrared semiconductor laser device 290 is bonded onto the upper surface 11b such that the active layer 293 and the ridge portion 295 are located below (on a Z2 side of) the n-type GaAs substrate 281. In other words, the infrared semiconductor laser device 290 is bonded onto the upper surface 11b in a junction-down system, so that the light-emitting region 290b is located on a side (lower side (Z2 side)) bonded to the upper surface 11b.

According to the second embodiment, a height from a lower surface 12 of the heat radiation substrate 10 to the active layer 33 of the red semiconductor laser device 230 in a vertical direction (direction Z) and a height from the lower surface 12 of the heat radiation substrate 10 to the active layer 293 of the infrared semiconductor laser device 290 in the vertical direction are substantially equal to each other, and the heights each are a height H4. Further, the height H4 is substantially equal to a height H3 from the lower surface 12 of the heat radiation substrate 10 to the active layer 23 of the blue-violet semiconductor laser device 220 in the vertical direction. Thus, the light-emitting region 220b of the blue-violet semiconductor laser device 220, the light-emitting region 230b of the red semiconductor laser device 230 and the light-emitting region 290b of the infrared semiconductor laser device 290 are located at the heights substantially equal to each other and arranged such that height positions of at least portions thereof overlap each other. A height (H2−H1) of the step portion 11c in the vertical direction is adjusted such that the light-emitting region 220b of the blue-violet semiconductor laser device 220, the light-emitting region 230b of the red semiconductor laser device 230 and the light-emitting region 290b of the infrared semiconductor laser device 290 are located at the heights substantially equal to each other.

The electrode 213b formed on the heat radiation substrate 10 and a lead terminal (on the anode side) (not shown) are electrically connected with each other through a wire 61. The p-side pad electrode 228 of the blue-violet semiconductor laser device 220 and a lead terminal (on the anode side) (not shown) are electrically connected with each other through a wire 62. The n-side electrode 283 of the two-wavelength semiconductor laser device 280 and the base portion 40 are electrically connected with each other through a wire 63. The electrode 213c formed on the heat radiation substrate 10 and the lead terminal (on the anode side) (not shown) are electrically connected with each other through a wire 264.

The remaining structure of the three-wavelength semiconductor laser apparatus 200 according to the second embodiment is similar to that of the two-wavelength semiconductor laser apparatus 100 according to the first embodiment.

A manufacturing process of the three-wavelength semiconductor laser apparatus 200 according to the second embodiment is now described with reference to FIGS. 3 and 6 to 8.

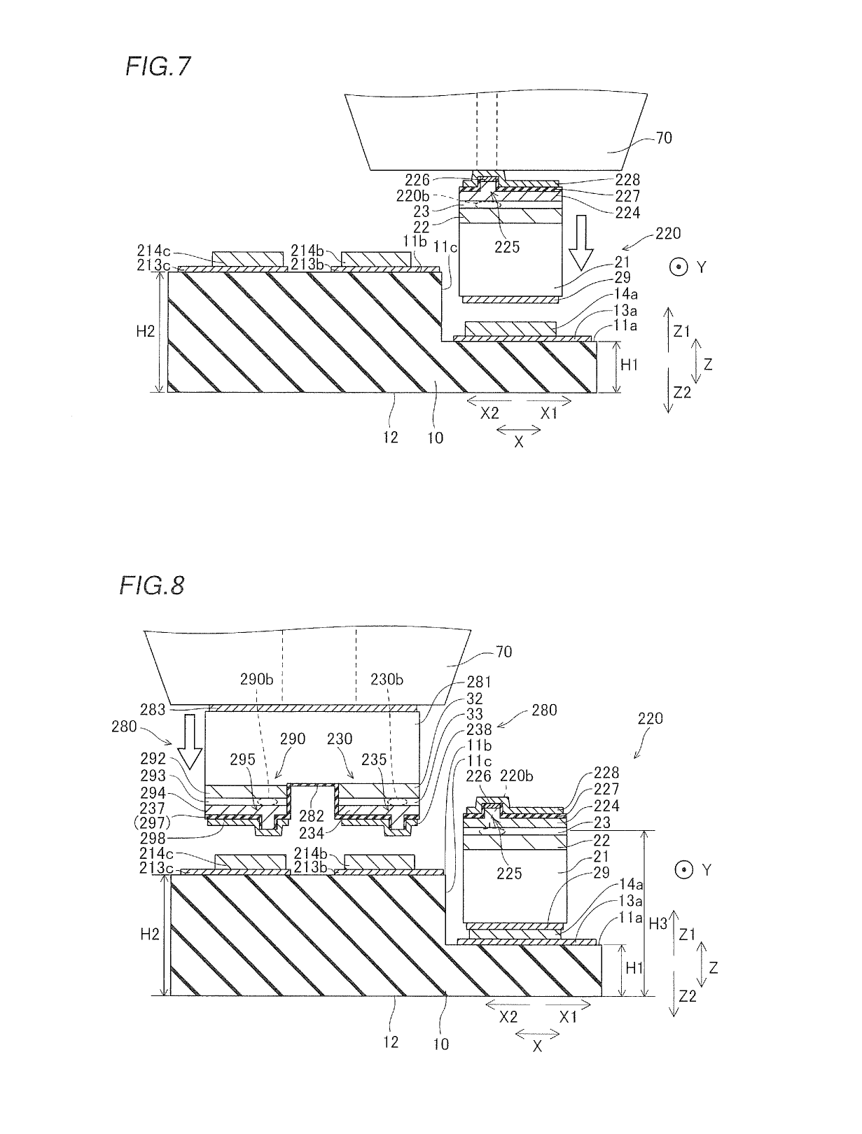

As shown in FIG. 3, the heat radiation substrate 10 having the upper surfaces 11a and 11b and the step portion 11c are first formed. Then, an electrode 13a is formed on the upper surface 11a of the heat radiation substrate 10, as shown in FIG. 7. The electrodes 213b and 213c are formed on the X1 and X2 sides, respectively, on the upper surface 11b of the heat radiation substrate 10. Thereafter, solder layers 14a, 214b and 214c are formed on the electrodes 13a, 213b and 213c, respectively.

The blue-violet semiconductor laser device 220 in which the ridge portion deviates to one side from the center in the direction X orthogonal to the emitting direction (direction Y) and the two-wavelength semiconductor laser device 280 having the red semiconductor laser device 230 and the infrared semiconductor laser device 290 monolithically formed in which the ridge portions deviate to one side from the centers in the direction X perpendicular to the emitting direction (direction Y) are formed through prescribed manufacturing processes. Then, an n-side electrode 29 of the blue-violet semiconductor laser device 220 and the electrode 13a are bonded to each other through the solder layer 14a melted by applying heat of about 300° C. The blue-violet semiconductor laser device 220 is bonded such that the ridge portion 225 deviates to the step portion 11c (X2 side) from the center of the blue-violet semiconductor laser device 220 in the direction X (horizontal direction). At this time, the blue-violet semiconductor laser device 220 is bonded onto the upper surface 11a of the heat radiation substrate 10 in a junction-up system, so that the light-emitting region 220b is located on the side (upper side (Z1 side)) opposite to the side bonded to the upper surface 11a. The blue-violet semiconductor laser device 220 is bonded onto the upper surface 11a such that the height from the lower surface 12 of the heat radiation substrate 10 to the active layer 23 of the blue-violet semiconductor laser device 220 in the vertical direction (direction Z) is H3 (see FIG. 8).

Thereafter, the n-side electrode 283 of the two-wavelength semiconductor laser device 280 is grasped from above (from a Z1 side) with a collet 70 such that the p-side electrode 238 of the red semiconductor laser device 230 and the solder layer 214b are opposed to each other while the p-side electrode 298 of the infrared semiconductor laser device 290 and the solder layer 214c are opposed to each other, as shown in FIG. 8. Then, the p-side electrode 238 of the red semiconductor laser device 230 and the electrode 213b are bonded to each other through the solder layer 214b melted by applying heat of about 300° C. The red semiconductor laser device 230 is bonded such that the ridge portion 235 deviates to the step portion 11c (X1 side) from the center of the red semiconductor laser device 230 in the direction X (horizontal direction). The p-side electrode 298 of the infrared semiconductor laser device 290 and the electrode 213c are bonded to each other through the solder layer 214c melted by applying heat of about 300° C. simultaneously with the bonding of the red semiconductor laser device 230. The infrared semiconductor laser device 290 is bonded such that the ridge portion 295 deviates to the step portion 11c (X1 side) from the center of the infrared semiconductor laser device 290 in the direction X (horizontal direction).

At this time, the red semiconductor laser device 230 and the infrared semiconductor laser device 290 are bonded onto the upper surface 11b of the heat radiation substrate 10 such that the height from the lower surface 12 of the heat radiation substrate 10 to the active layer 33 of the red semiconductor laser device 230 in the vertical direction (direction Z) and the height from the lower surface 12 of the heat radiation substrate 10 to the active layer 293 of the infrared semiconductor laser device 290 in the vertical direction are H4 (see FIG. 6). Thus, the light-emitting region 220b of the blue-violet semiconductor laser device 220, the light-emitting region 230b of the red semiconductor laser device 230 and the light-emitting region 290b of the infrared semiconductor laser device 290 are located at the heights substantially equal to each other and arranged such that the height positions of at least the portions thereof overlap each other. The red semiconductor laser device 230 and the infrared semiconductor laser device 290 of the two-wavelength semiconductor laser device 280 are bonded onto the upper surface 11b of the heat radiation substrate 10 in a junction-down system, so that the light-emitting regions 230b and 290b are located on the side (lower side (Z2 side)) bonded to the upper surface 11b.

Thereafter, the heat radiation substrate 10 is bonded to the base portion 40 through a bonding layer 50, as shown in FIG. 6. At this time, the upper surfaces 11a and 11b and the lower surface 12 of the heat radiation substrate 10 are horizontally arranged. Then, the electrode 13a and the base portion 40 are connected with each other through a wire 60. The electrode 213b and the lead terminal (on the anode side) (not shown) are connected with each other through the wire 61. The p-side pad electrode 228 and the lead terminal (on the anode side) (not shown) are connected with each other through the wire 62. The n-side electrode 283 and the base portion 40 are connected with each other through the wire 63. The electrode 213c and the lead terminal (on the anode side) (not shown) are connected with each other through the wire 264. Thus, the three-wavelength semiconductor laser apparatus 200 is formed.

The remaining manufacturing process of the three-wavelength semiconductor laser apparatus 200 according to the second embodiment is similar to that of the two-wavelength semiconductor laser apparatus 100 according to the first embodiment.

According to the second embodiment, as hereinabove described, the light-emitting region 220b of the blue-violet semiconductor laser device 220 is formed at a position deviating to the step portion 11c (X2 side) from the center of the blue-violet semiconductor laser device 220 in the direction X while the light-emitting region 230b of the red semiconductor laser device 230 is formed at a position deviating to the step portion 11c (X1 side) from the center of the red semiconductor laser device 230 in the direction X and the light-emitting region 290b of the infrared semiconductor laser device 290 is formed at a position deviating to the step portion 11c (X1 side) from the center of the infrared semiconductor laser device 290 in the direction X. Thus, the light-emitting region 220b and the light-emitting regions 230b and 290b can be rendered closer to the step portion 11c, and hence the light-emitting region 220b of the blue-violet semiconductor laser device 220 and the light-emitting regions 230b and 290b of the red and infrared semiconductor laser devices 230 and 290 can be rendered close to each other in the horizontal direction (direction X).

According to the second embodiment, the red semiconductor laser device 230 and the infrared semiconductor laser device 290 are monolithically formed on the same n-type GaAs substrate 281, whereby in the three-wavelength semiconductor laser apparatus 200 comprising the blue-violet semiconductor laser device 220 bonded onto the upper surface 11a and the two-wavelength semiconductor laser device 280 including the red semiconductor laser device 230 and the infrared semiconductor laser device 290 both bonded onto the upper surface 11b and monolithically formed on the same n-type GaAs substrate 281, the height (H3) of the light-emitting region 220b in the blue-violet semiconductor laser device 220 and the heights (H4) of the light-emitting regions 230b and 290b in the red and infrared semiconductor laser devices 230 and 290 can be rendered close to each other. Further, the red semiconductor laser device 230 and the infrared semiconductor laser device 290 are formed on the common n-type GaAs substrate 281, whereby deviation between a height position of the light-emitting region 230b of the red semiconductor laser device 230 and a height position of the light-emitting region 290b of the infrared semiconductor laser device 290 can be inhibited when the red semiconductor laser device 230 and the infrared semiconductor laser device 290 are bonded to the heat radiation substrate 10.

According to the second embodiment, the two-wavelength semiconductor laser device 280 includes the light-emitting regions 230b and 290b, and the height positions of at least the portions of the light-emitting region 220b of the blue-violet semiconductor laser device 220 and each of the light-emitting regions 230b and 290b of the two-wavelength semiconductor laser device 280 overlap each other in a state where the heat radiation substrate 10 is horizontally arranged. Thus, the height position of the light-emitting region 220b and the height positions of the light-emitting regions 230b and 290b plurally provided can be reliably rendered close to each other, and hence deviation in a height direction between an application position of a laser beam from the blue-violet semiconductor laser device 220 and application positions of a plurality of laser beams from the two-wavelength semiconductor laser device 280 can be reliably inhibited from increase.

According to the second embodiment, the red semiconductor laser device 230 and the infrared semiconductor laser device 290 having the different lasing wavelengths from each other are bonded onto the upper surface 11b through the groove portion 282. The light-emitting regions 230b and 290b of the red and infrared semiconductor laser devices 230 and 290 are arranged at the positions deviating to the step portion 11c from the centers of respective device bodies in a state where the heat radiation substrate 10 is horizontally arranged. Thus, the light-emitting regions 230b and 290b of the red and infrared semiconductor laser devices 230 and 290 can be rendered closer to the step portion 11c also when forming the three-wavelength semiconductor laser apparatus 200, and hence optical axes of the laser beams in the respective semiconductor laser devices can be easily aligned. The remaining effects of the second embodiment are similar to those of the first embodiment.

### Third Embodiment

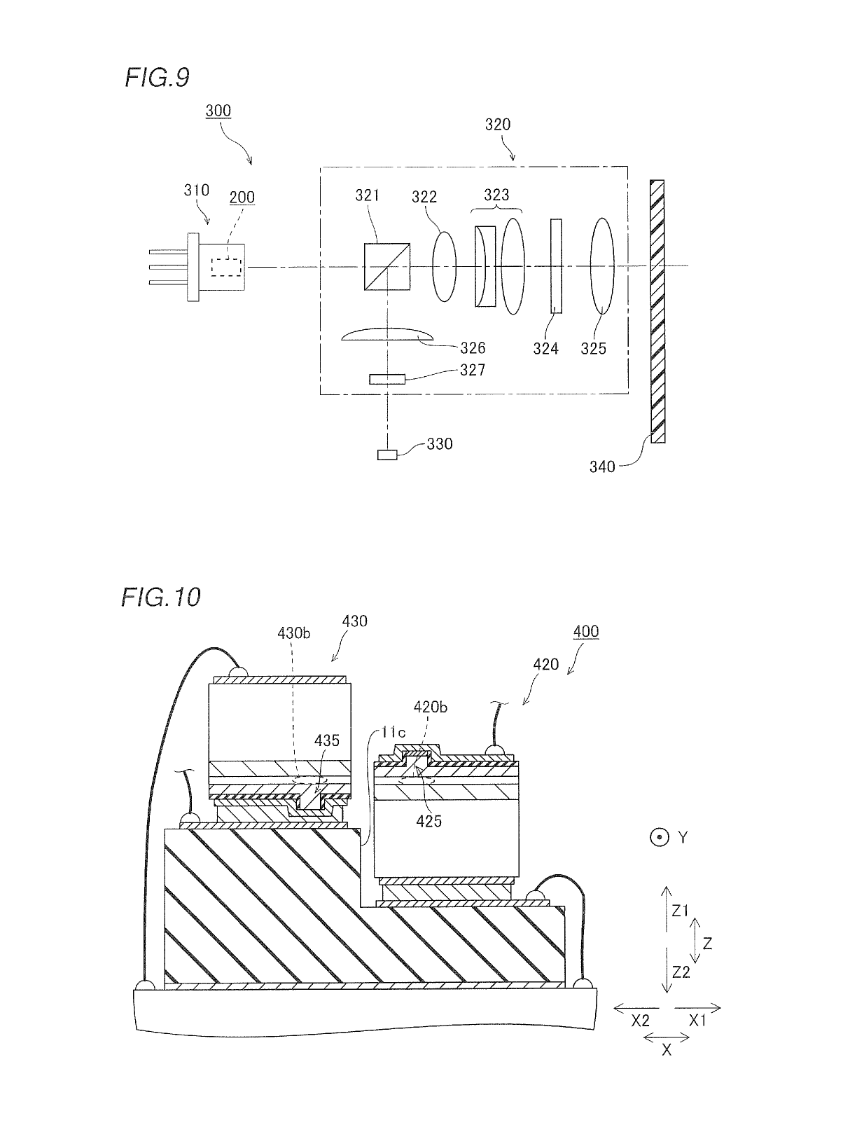

An optical pickup 300 according to a third embodiment of the present invention is now described with reference to FIGS. 6 and 9. The optical pickup 300 is an example of the “optical apparatus” in the present invention.

The optical pickup 300 according to the third embodiment of the present invention comprises a can-type three-wavelength semiconductor laser apparatus 310 mounted with the three-wavelength semiconductor laser apparatus 200 according to the second embodiment, an optical system 320 adjusting laser beams emitted from the three-wavelength semiconductor laser apparatus 310 and a light detection portion 330 receiving the laser beams, as shown in FIG. 9.

The optical system 320 has a polarizing beam splitter (PBS) 321, a collimator lens 322, a beam expander 323, a λ/4 plate 324, an objective lens 325, a cylindrical lens 326 and an optical axis correction device 327.

The PBS 321 totally transmits the laser beams emitted from the three-wavelength semiconductor laser apparatus 310, and totally reflects the laser beams fed back from an optical disc 340. The collimator lens 322 converts the laser beams emitted from the three-wavelength semiconductor laser apparatus 310 and transmitted through the PBS 321 to parallel beams. The beam expander 323 is constituted by a concave lens, a convex lens and an actuator (not shown). The actuator has a function of correcting wave surface states of the laser beams emitted from the three-wavelength semiconductor laser apparatus 310 by varying a distance between the concave lens and the convex lens.

The λ/4 plate 324 converts the linearly polarized laser beams, substantially converted to the parallel beams by the collimator lens 322, to circularly polarized beams. Further, the λ/4 plate 324 converts the circularly polarized laser beams fed back from the optical disc 340 to linearly polarized beams. A direction of linear polarization in this case is orthogonal to a direction of linear polarization of the laser beams emitted from the three-wavelength semiconductor laser apparatus 310. Thus, the PBS 321 substantially totally reflects the laser beams fed back from the optical disc 340. The objective lens 325 converges the laser beams transmitted through the λ/4 plate 324 on a surface (recording layer) of the optical disc 340. An objective lens actuator (not shown) renders the objective lens 325 movable.

The cylindrical lens 326, the optical axis correction device 327 and the light detection portion 330 are arranged to be along optical axes of the laser beams totally reflected by the PBS 321. The cylindrical lens 326 provides the incident laser beams with astigmatic action. The optical axis correction device 327 is constituted by a diffraction grating and so arranged that spots of zero-order diffracted beams of blue-violet, red and infrared laser beams transmitted through the cylindrical lens 326 coincide with each other on a detection region of the light detection portion 330 described later.

The light detection portion 330 outputs a playback signal on the basis of intensity distribution of the received laser beams. Thus, the optical pickup 300 comprising the three-wavelength semiconductor laser apparatus 310 is formed.

In this optical pickup 300, the three-wavelength semiconductor laser apparatus 310 can independently emit blue-violet, red and infrared laser beams from the blue-violet semiconductor laser device 220, the red semiconductor laser device 230 and the infrared semiconductor laser device 290 (see FIG. 6). The laser beams emitted from the three-wavelength semiconductor laser apparatus 310 are adjusted by the PBS 321, the collimator lens 322, the beam expander 323, the λ/4 plate 324, the objective lens 325, the cylindrical lens 326 and the optical axis correction device 327 as described above, and thereafter applied onto the detection region of the light detection portion 330.

When data recorded in the optical disc 340 is play backed, the laser beams emitted from the blue-violet semiconductor laser device 220, the red semiconductor laser device 230 and the infrared semiconductor laser device 290 are controlled to have constant power and applied to the recording layer of the optical disc 340, so that the playback signal outputted from the light detection portion 330 can be obtained. When data is recorded in the optical disc 340, the laser beams emitted from the blue-violet semiconductor laser device 220 and the red semiconductor laser device 230 (infrared semiconductor laser device 290) are controlled in power and applied to the optical disc 340, on the basis of the data to be recorded. Thus, the data can be recorded in the recording layer of the optical disc 340. Thus, the data can be recorded in or played back from the optical disc 340 with the optical pickup 300 comprising the three-wavelength semiconductor laser apparatus 310.

According to the third embodiment, as hereinabove described, the optical pickup 300 comprises the three-wavelength semiconductor laser apparatus 200 according to the second embodiment, whereby deviation in a height direction between an application position (spot) of the laser beam from the blue-violet semiconductor laser device 220, an application position of the laser beam from the red semiconductor laser device 230 and an application position of the laser beam from the infrared semiconductor laser device 290 can be inhibited from increase when the laser beams are applied to the optical disc 340 through the optical system 320.

Although the present invention has been described and illustrated in detail, it is clearly understood that the same is by way of illustration and example only and is not to be taken by way of limitation, the spirit and scope of the present invention being limited only by the terms of the appended claims.

For example, while the ridge portion 25 is formed in the substantially central portion of the blue-violet semiconductor laser device 20 in the direction X, and the ridge portion 35 is formed in the substantially central portion of the red semiconductor laser device 30 in the direction X in the aforementioned first embodiment, the present invention is not restricted to this. In the present invention, a light-emitting region 420b (ridge portion 425) of a blue-violet semiconductor laser device 420 may deviate to the step portion 11c (X2 side) from a center of the blue-violet semiconductor laser device 420 in the direction X (horizontal direction), and a light-emitting region 430b (ridge portion 435) of a red semiconductor laser device 430 may deviate to the step portion 11c (X1 side) from a center of the red semiconductor laser device 430 in the direction X (horizontal direction) as in a two-wavelength semiconductor laser apparatus 400 according to a modification of the first embodiment shown in FIG. 10. Alternatively, either the ridge portion of the blue-violet semiconductor laser device or the ridge portion of the red semiconductor laser device may deviate to the step portion, and either the ridge portion of the red semiconductor laser device or the ridge portion of the blue-violet semiconductor laser device may be formed in the substantially central portion of a device body. The two-wavelength semiconductor laser apparatus 400, the blue-violet semiconductor laser device 420 and the red semiconductor laser device 430 are examples of the “semiconductor laser apparatus”, the “first semiconductor laser device” and the “second semiconductor laser device” in the present invention, respectively. The ridge portions 425 and 435 are examples of the “first ridge portion” and the “second ridge portion” in the present invention, respectively.

While the two-wavelength semiconductor laser apparatus 100 includes the blue-violet semiconductor laser device 20 bonded onto the upper surface 11a of the heat radiation substrate 10 and the red semiconductor laser device 30 bonded onto the upper surface 11b of the heat radiation substrate 10 in the aforementioned first embodiment, and the three-wavelength semiconductor laser apparatus 200 includes the blue-violet semiconductor laser device 220 bonded onto the upper surface 11a of the heat radiation substrate 10 and the two-wavelength semiconductor laser device 280 having the red semiconductor laser device 230 and the infrared semiconductor laser device 290 both bonded onto the upper surface 11b of the heat radiation substrate 10 and monolithically formed in the aforementioned second embodiment, the present invention is not restricted to this. In the present invention, a green semiconductor laser device or a blue semiconductor laser device made of a nitride-based semiconductor may be employed in place of the blue-violet semiconductor laser device in each of the aforementioned first and second embodiments. An infrared semiconductor laser device may be employed in place of the red semiconductor laser device in the aforementioned first embodiment. The three-wavelength semiconductor laser apparatus of the aforementioned second embodiment may include the red semiconductor laser device, a green semiconductor laser device and a blue semiconductor laser device. Thus, the three-wavelength semiconductor laser apparatus having three primary colors of RGB can be formed. At this time, the green semiconductor laser device and the blue semiconductor laser device are preferably arranged on the upper surface 11a of the heat radiation substrate 10, and the red semiconductor laser device is preferably arranged on the upper surface 11b of the heat radiation substrate 10.

While the first light-emitting region (the light-emitting regions 20b and 220b) of the first semiconductor laser device (the blue-violet semiconductor laser devices 20 and 220) and the second light-emitting region (the light-emitting regions 30b, 230b and 290b) of the second semiconductor laser device (the red semiconductor laser devices 30 and 230 and the infrared semiconductor laser device 290) are located at the heights substantially equal to each other and arranged such that the height positions of at least the portions thereof overlap each other in the aforementioned first and second embodiments, the present invention is not restricted to this. In the present invention, the height position of the first light-emitting region and the height position of the second light-emitting region may not overlap each other as long as the first light-emitting region of the first semiconductor laser device and the second light-emitting region of the second semiconductor laser device are located at heights close to each other.

While the height (H2−H1) of the step portion 11c in the vertical direction is adjusted such that the light-emitting regions 20b and 220b of the blue-violet semiconductor laser devices 20 and 220, the light-emitting regions 30b and 230b of the red semiconductor laser devices 30 and 230 and the light-emitting region 290b of the infrared semiconductor laser device 290 are located at the heights substantially equal to each other in the aforementioned first and second embodiments, the present invention is not restricted to this. In the present invention, the height position of the first light-emitting region in the first semiconductor laser device (the blue-violet semiconductor laser device) or the height position of the second light-emitting region in the second semiconductor laser device (the red semiconductor laser device and the infrared semiconductor laser device) may be adjusted without adjusting the height of the step portion in the vertical direction. Alternatively, thicknesses, in the vertical direction, of the electrode and the solder layer formed on the upper surface (first upper surface) on which the first semiconductor laser device is arranged may be adjusted, or thicknesses, in the vertical direction, of the electrode and the solder layer formed on the upper surface (second upper surface) on which the second semiconductor laser device is arranged may be adjusted.

While the blue-violet semiconductor laser devices 20 and 220 are bonded onto the upper surface 11a (first upper surface) in a junction-up system, and the red semiconductor laser devices 30 and 230 and the infrared semiconductor laser device 290 are bonded onto the upper surface 11b (second upper surface) located above the upper surface 11a (first upper surface) in a junction-down system in the aforementioned first and second embodiments, the present invention is not restricted to this. In the present invention, the red semiconductor laser device and the infrared semiconductor laser device may be bonded onto the first upper surface in a junction-up system, and the blue-violet semiconductor laser device may be bonded onto the second upper surface located above the first upper surface in a junction-down system. At this time, at least the light-emitting region of the red semiconductor laser device and the light-emitting region of the infrared semiconductor laser device must be located above the second upper surface.

While the heat radiation substrate 10 is made of AlN having insulating properties in each of the aforementioned first and second embodiments, the present invention is not restricted to this. The heat radiation substrate may be made of undoped Si having insulating properties, for example.

While the current blocking layers 27 and 37, 227, 237 and 297 are made of SiO₂ in the aforementioned first and second embodiments, the present invention is not restricted to this. In the present invention, another insulating material such as SiN or a semiconductor material such as AlInP or AlGaN may be employed as the current blocking layers.

While the aforementioned three-wavelength semiconductor laser apparatus 200 according to the second embodiment is mounted on the can-type three-wavelength semiconductor apparatus 310 in the aforementioned third embodiment, the present invention is not restricted to this. In the present invention, the aforementioned three-wavelength semiconductor laser apparatus 200 according to the second embodiment may be mounted on a frame-type three-wavelength semiconductor laser apparatus having a plate-like planar structure.

What is claimed is:

1. A semiconductor laser apparatus comprising:
a base including a step portion, a first upper surface on a lower side of said step portion and a second upper surface on an upper side of said step portion;
a first semiconductor laser device bonded onto said first upper surface, including a first light-emitting region on an upper side thereof; and
a second semiconductor laser device bonded onto said second upper surface, including a second light-emitting region on a lower side thereof, wherein
said first light-emitting region is located above said second upper surface in a state where said base is horizontally arranged.

2. The semiconductor laser apparatus according to claim 1, wherein
said first light-emitting region of said first semiconductor laser device and said second light-emitting region of said second semiconductor laser device are located at heights equal to each other or close to each other in a state where said base is horizontally arranged.

3. The semiconductor laser apparatus according to claim 2, wherein
said first light-emitting region of said first semiconductor laser device and said second light-emitting region of said second semiconductor laser device are arranged such that height positions of at least portions thereof overlap each other in a state where said base is horizontally arranged.

4. The semiconductor laser apparatus according to claim 2, wherein
said first light-emitting region and said second light-emitting region extend along emitting directions of laser beams from said first semiconductor laser device and said second semiconductor laser device, respectively, and
said first light-emitting region and said second light-emitting region are located at heights equal to each other or close to each other along said emitting directions of laser beams.

5. The semiconductor laser apparatus according to claim 2, wherein
a height of said step portion from said first upper surface to said second upper surface is adjusted such that said first light-emitting region of said first semiconductor laser device and said second light-emitting region of said second semiconductor laser device are located at heights equal to each other or close to each other in a state where said base is horizontally arranged.

6. The semiconductor laser apparatus according to claim 1, wherein
said first semiconductor laser device includes a first surface closer to said first light-emitting region and a second surface farther from said first light-emitting region, opposite to said first surface, and
said second surface of said first semiconductor laser device is bonded onto said first upper surface.

7. The semiconductor laser apparatus according to claim 6, wherein
said second semiconductor laser device includes a third surface closer to said second light-emitting region and a fourth surface farther from said second light-emitting region, opposite to said third surface, and
said third surface of said second semiconductor laser device is bonded onto said second upper surface.

8. The semiconductor laser apparatus according to claim 7, wherein
the amount of heat generation in said second semiconductor laser device is larger than the amount of heat generation in said first semiconductor laser device.

9. The semiconductor laser apparatus according to claim 7, wherein
said fourth surface of said second semiconductor laser device is located above said first surface of said first semiconductor laser device.

10. The semiconductor laser apparatus according to claim 1, wherein
said step portion is formed to extend along emitting directions of laser beams from said first semiconductor laser device and said second semiconductor laser device.

11. The semiconductor laser apparatus according to claim 10, wherein
said first semiconductor laser device includes a first ridge portion for forming said first light-emitting region, and said second semiconductor laser device includes a second ridge portion for forming said second light-emitting region,
said first ridge portion and said second ridge portion extend along said emitting directions of laser beams from said first semiconductor laser device and said second semiconductor laser device, respectively, and
a distance from said step portion to at least either said first ridge portion or said second ridge portion in a horizontal direction is substantially constant along said emitting directions of laser beams.

12. The semiconductor laser apparatus according to claim 2, wherein
said second semiconductor laser device includes a plurality of said second light-emitting regions, and
said first light-emitting region of said first semiconductor laser device and each of said plurality of second light-emitting regions of said second semiconductor laser device are arranged such that height positions of at least portions thereof overlap each other in a state where said base is horizontally arranged.

13. The semiconductor laser apparatus according to claim 1, wherein
at least either said first light-emitting region of said first semiconductor laser device or said second light-emitting region of said second semiconductor laser device is arranged at a position deviating to said step portion from a center of a device body.

14. The semiconductor laser apparatus according to claim 13, wherein
said second semiconductor laser device includes two said second semiconductor laser devices having different lasing wavelengths from each other,
two said semiconductor laser devices are bonded onto said second upper surface at a prescribed interval from each other, and
said second light-emitting region of each of two said second semiconductor laser devices is arranged at a position deviating to said step portion from a center of each device body.

15. The semiconductor laser apparatus according to claim 1, wherein
said first semiconductor laser device is made of a nitride-based semiconductor.

16. The semiconductor laser apparatus according to claim 1, wherein
said second semiconductor laser device includes at least either a red semiconductor laser device made of a GaInP-based semiconductor or an infrared semiconductor laser device made of a GaAs-based semiconductor.

17. The semiconductor laser apparatus according to claim 1, wherein
said base is a heat radiation substrate.

18. The semiconductor laser apparatus according to claim 17, wherein
said heat radiation substrate has insulating properties,
the semiconductor laser apparatus further comprising:
a first electrode formed on said first upper surface of said step portion, to which said first semiconductor laser device is bonded; and
a second electrode formed on said second upper surface of said step portion, to which said second semiconductor laser device is bonded.

19. The semiconductor laser apparatus according to claim 18, wherein
said first electrode and said second electrode are separated from each other by said step portion, and
a bonding wire is bonded to each of said first electrode and said second electrode.

20. An optical apparatus comprising:
a semiconductor laser apparatus including a base having a step portion, a first upper surface on a lower side of said step portion and a second upper surface on an upper side of said step portion, a first semiconductor laser device bonded onto said first upper surface, having a first light-emitting region on an upper side thereof and a second semiconductor laser device bonded onto said second upper surface, having a second light-emitting region on a lower side thereof; and
an optical system controlling a laser beam emitted from said semiconductor laser apparatus, wherein
said first light-emitting region is located above said second upper surface in a state where said base is horizontally arranged.
